(19) United States
(12) Patent Application Publication
(10) Pub. No.: US 2016/0209344 A1
(43) Pub. Date: Jul. 21, 2016

(54) COMPLEX SENSOR AND METHOD OF MANUFACTURING THE SAME

(71) Applicant: Samsung Electro-Mechanics Co., Ltd., Suwon-si (KR)

(72) Inventor: Tae Hun LEE, Suwon-si (KR)

(73) Assignee: Samsung Electro-Mechanics Co., Ltd., Suwon-si (KR)

(21) Appl. No.: 14/881,667

(22) Filed: Oct. 13, 2015

(30) Foreign Application Priority Data
Jan. 15, 2015 (KR) 10-2015-0007400

(51) Int. Cl. G01N 27/02; G01K 7/16; G01L 9/00; H01L 25/16; H01L 25/00

(52) U.S. Cl. CPC G01N 27/028; H01L 25/16; H01L 25/50; G01L 9/0052; G01K 7/16

(57) ABSTRACT

A complex sensor, a package including a complex sensor and a method of manufacturing the same are provided. The complex sensor includes a base, a first sensor unit disposed on a first surface of the base, and a second sensor unit disposed on a second surface of the base.

### CROSS-REFERENCE TO RELATED APPLICATION

This application claims the benefit under 35 USC 119(a) of Korean Patent Application No. 10-2015-0007400 filed on Jan. 15, 2015, in the Korean Intellectual Property Office, the entire disclosure of which is incorporated herein by reference for all purposes.

### BACKGROUND

1. Field

The present disclosure relates to a complex sensor, a sensor package and a method of manufacturing the same.

2. Description of Related Art

With the recent development of sensor technology, there has been efforts to develop a complex sensor integrated within a subminiature package. For example, a configuration in which a pressure sensor, a temperature sensor, and a humidity sensor are disposed in a package having an open cavity structure has been researched.

To this end, a method of attaching individual sensor chips to a single body and forming individual sensor chips attached to the body as a single package has been proposed. However, this method has limitations in regard to miniaturization of the package.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a complex sensor including a base, a first sensor unit disposed on a first surface of the base, and a second sensor unit disposed on a second surface of the base.

The first sensor unit may be disposed on an upper surface of the base, and the second sensor unit is disposed on a lower surface of the base.

The first sensor unit may include at least one of a pressure sensor and a temperature sensor, and the second sensor unit includes at least one of a humidity sensor and a gas sensor.

The second sensor unit includes a porous silicon layer.

The general aspect of the complex sensor further includes a plurality of external terminals disposed on the lower surface of the base and electrically connected to the second sensor unit.

The second sensor unit may include a porous silicon layer and electrodes disposed on the porous silicon layer.

The porous silicon layer may be obtained by electrolyzing a portion of the base.

The pressure sensor may include a diaphragm closing a cavity provided in the base and at least one piezoresistor disposed on the diaphragm.

The temperature sensor may include a pattern resistor disposed on one surface of the base.

The second sensor unit may be electrically connected to an external element through external terminals disposed on a lower surface of the base, and the first sensor unit may be electrically connected to the external element through a bonding wire.

In another general aspect, a method of manufacturing a complex sensor involves forming a first sensor unit on a first surface of a base, and forming a second sensor unit on a second surface of the base.

The forming of the first sensor unit may include forming a pressure sensor, and the forming of the pressure sensor involves: forming a cavity in a first substrate, stacking a second substrate on the first substrate to close the cavity, and forming at least one piezoresistor on the second substrate.

The forming of the second sensor unit involves forming at least one porous silicon layer on the other surface of the base, and forming electrodes on the porous silicon layer.

The forming of the porous silicon layer involves forming a mask on the other surface of the base formed of silicon, and forming the porous silicon layer by etching the other surface of the base using hydrofluoric acid (HF).

The forming of the second sensor unit may involve forming a humidity sensor and a gas sensor using the porous silicon layer.

The forming of the first sensor unit involves forming a temperature sensor, and the forming of the temperature sensor may involve forming a pattern resistor on the second substrate, after the forming of the piezo-resistor.

In another general aspect, a complex sensor package involves the general aspect of the complex sensor described above, and an electronic element on which the complex sensor is mounted such that both the first surface and the second surface of the base are exposed to air.

The general aspect of the complex sensor package may further include a cover forming a cavity therein, and the complex sensor may be disposed in the cavity such that the first surface and the second surface of the base are exposed to the air inside the cavity.

Other features and aspects will be apparent from the following detailed description, the drawings, and the claims.

### BRIEF DESCRIPTION OF DRAWINGS

FIG. 1 is a cross-sectional view of an example of a complex sensor package according to the present disclosure.

FIGS. 2 through 7 are cross-sectional views illustrating an example of a method of manufacturing a complex sensor package according to the present disclosure.

FIG. 8 is a cross-sectional view of another example of a complex sensor package according to in the present disclosure.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

In the drawings, the shapes and dimensions of elements may be exaggerated for clarity, and the same reference numerals will be used throughout to designate the same or like elements.

According to one example, the present disclosure provides a complex sensor of a significantly decreased size, a package including the same, and a method of manufacturing the same.

According to one example, a pressure sensor, a temperature sensor, and a humidity sensor are disposed in a single microelectromechanical systems (MEMS) chip.

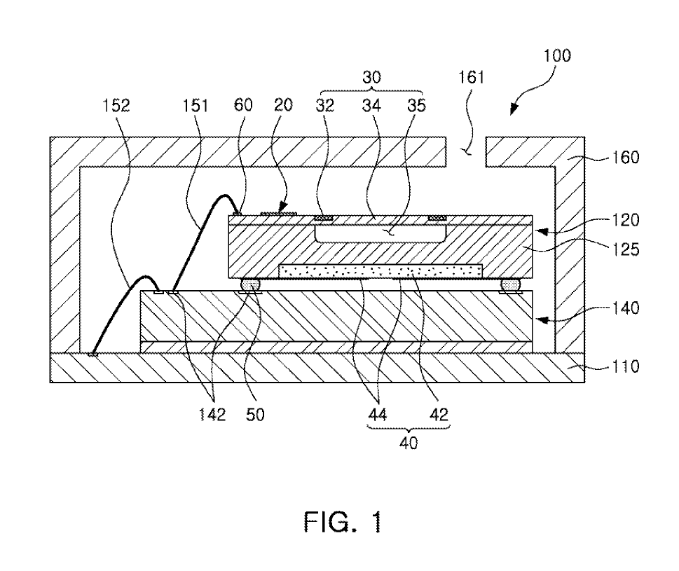

FIG. 1 illustrates a cross-sectional view of an example of a complex sensor package.

Referring to FIG. 1, the example of the complex sensor package 100 includes a package substrate 110, an electronic element 140, a complex sensor 120, and a cover 160. In addition, the complex sensor package 100 may further include other elements required for operating the complex sensor 120.

For the package substrate 110, various kinds of substrates (for example, a ceramic substrate, a printed circuit board (PCB), a flexible substrate, and the like) may be used. In addition, at least one surface of the package substrate 110 is provided with mounting electrodes on which the complex sensor 120 or the electronic element 140 may be mounted, and a wiring pattern electrically connects the mounting electrodes to each other.

In this example, the package substrate 110 may be a multilayer substrate including a plurality of layers, and a circuit pattern for electrical connections may be formed between the plurality of layers. However, the package substrate is not limited thereto; in other example, the package substrate may be a single-layer substrate.

Further, the package substrate 110 includes external connection pads (not illustrated) formed on a lower surface thereof. The external connection pads may be provided in order to electrically connect the substrate to a main board 1, and may have external terminals (not illustrated) bonded thereto.

In addition, one or more electronic components may be mounted on or embedded in the package substrate 110. Here, the electronic components may include both a passive element and an active element.

The package substrate 110 may be mounted on the main board (not illustrated), and may be electrically connected to the main board through a plurality of external terminals (for example, solder balls, or the like). The external terminals may be a solder ball, a solder bump, or the like; however, the types of terminal terminals are not limited thereto.

In addition, various modifications may be made. For example, after a lower surface of the package substrate 110 is bonded to the surface of the main board, the package substrate 110 may be electrically connected to the main board through bonding wires.

In this example, the electronic element 140, a semiconductor element, is an application-specific integrated circuit (ASIC). However, the electronic element 140 is not limited thereto; in another example, the electronic element may include other general electronic elements.

The electronic element 140 may be electrically connected to the package substrate 110 or the complex sensor 120 through solder balls, or the like. To this end, at least one electrode 142 may be formed on an upper surface of the electronic element.

The complex sensor 120 according to the present example may be mounted in a portable terminal, a small electronic device, or the like. In addition, the complex sensor 120 may be manufactured to be of a subminiature size through microelectromechanical systems (MEMS) technology, and may provide information on the environment of devices in which the complex sensor 120 is mounted.

The complex sensor 120 illustrated in FIG. 1 includes a base 125 forming a body and a plurality of sensors 20, 30, and 40 formed on both surfaces of the base 125.

The base 125 may be formed of single-crystal silicon or silicon-on-insulator (SOI). In addition, the base 125 may have the form of a substrate in which one or more silicon layers are stacked.

In this example, first sensor unit comprising a plurality of sensors 20 and 30 are disposed on one surface (for example, an upper surface) of the base 125. The first sensor unit includes a pressure sensor 30 and a temperature sensor 20. However, the first sensor unit is not limited thereto, and may only include one of either the pressure sensor 30 or the temperature sensor 20, and may further include another sensor such as, for example, an acceleration sensor, or the like.

The pressure sensor 30 may include a plurality of piezoresistors 32. For example, in the pressure sensor 30, according to the illustrated example, the plurality of piezoresistors 32 having electrical resistances that are changed depending on mechanical stress may be configured in a bridge circuit to measure changes in electrical resistances when a predetermined level of pressure is applied to a diaphragm 34, thereby sensing the level of the applied pressure.

To this end, the pressure sensor 30 includes a cavity 35, an enclosed space, and the diaphragm 34.

The cavity 35 is formed in the base 125 and is a void or in vacuum state. In addition, the cavity 35 is closed by the diaphragm 34, and the piezoresistors 32 may be disposed on the diaphragm 34.

The piezoresistors 32 may be formed by doping specific regions of the diaphragm 34 formed of silicon with boron, phosphorus, or the like. In addition, the piezoresistors 32 may be electrically connected to an upper electrode 60 through a wiring pattern (not illustrated) formed on the base 125.

In the event that an external pressure is applied to the complex sensor package 100, stress corresponding to the external pressure may be generated in the diaphragm 34, and resistance values of the piezoresistors 32 formed in the diaphragm 34 may be changed due to changes in stress.

Therefore, a voltage value corresponding to a change in the resistance values of the piezoresistors 32 may be detected by the pressure sensor 30 to calculate the external pressure.

In this example, the temperature sensor 20 is disposed on one surface of the base 125 to be spaced apart from the pressure sensor 30.

The temperature sensor 20 as illustrated in FIG. 1 may include a resistor pattern (for example, a zigzag pattern) formed of a material of which a resistance value is in proportion to temperature change, such as platinum (Pt), nickel (Ni) or polysilicon.

For example, the temperature sensor 20 may be a resistor temperature detector (RTD) detecting a resistance value of the resistor pattern to sense temperature.

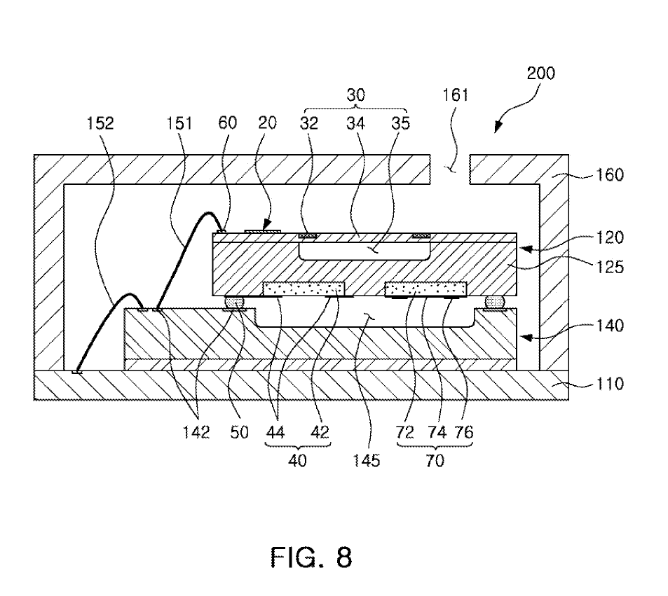

In this example, a second sensor unit is disposed on the other surface (for example, a lower surface) of the base 125. In this example, the second sensor unit includes a humidity sensor 40. However, the second sensor unit is not limited thereto, and may also include both the humidity sensor 40 and a gas sensor 70, as illustrated in FIG. 8 to be described below, or may only include one of either the humidity sensor 40 or the gas sensor 70. In addition, the second sensor unit may further include another sensor, if necessary.

In this example, a capacitive relative humidity sensor is illustrated as the humidity sensor 40. The humidity sensor 40 includes electrodes 44 and a porous silicon layer 42 disposed between the electrodes 44.

The porous silicon layer 42 may be formed by electrolyzing a silicon substrate in hydrofluoric acid (HF). Generally, a p+ or p type silicon region may react to the hydrofluoric acid to be changed into a porous region.

Therefore, the porous silicon layer 42 according to the illustrated example may be formed by allowing a portion of the base 125 formed of silicon to react with hydrofluoric acid.

The electrodes 44 may be formed on the porous silicon layer 42, and may be electrically connected to external terminals 50 through a wiring pattern (not illustrated).

Solder balls, solder bumps, or the like, may be used as the external electrodes 50, and a plurality of external terminals may be disposed on the lower surface of the base 125 and be electrically connected to the electrodes of the humidity sensor 40.

As illustrated in FIG. 1, the complex sensor 120 configured as described above may be mounted on the upper surface of the electronic element 140. In FIG. 1, the external terminals 50 of the complex sensor 120 is bonded to the electrodes 142 formed on the upper surface of the electronic element 140.

In addition, the upper electrode 60 formed on the upper surface of the complex sensor 120 is electrically connected to the electronic element 140 through a bonding wire 151.

Referring to FIG. 1, therefore, the temperature sensor 20 and the pressure sensor 30 are electrically connected to the electronic element 140 through the bonding wire 151, and the humidity sensor 40 is electrically connected to the electronic element 140 through the external terminals 50.

In this example, the cover 160 has a cap shape having an accommodating space formed therein, and may be formed of a metal. However, in another example, the cover 160 is not necessarily formed thereof, and may be formed of a mixture containing metal powder, if necessary.

The cover 160 is bonded to edges of the package substrate 110 to cover the complex sensor 120 and the electronic element 140. In addition, the cover 160 may be electrically connected to the package substrate 110, and may be electrically connected to a ground of the package substrate 110, if necessary.

Therefore, the cover 160 may protect the complex sensor 120 and the electronic element 140 from harmful electromagnetic waves.

In addition, the cover 160 may have at least one through-hole 161 formed therein. The through-hole 161 may be used as a path through which air is introduced or discharged.

In the complex sensor package 100 configured as described above, sensors 20, 30, and 40 are disposed on both surfaces of the complex sensor 120. Therefore, a size of the complex sensor 120 may be significantly decreased. Further, with the reduced size of the complex sensor 120, a size of the complex sensor package 100 may also be significantly decreased.

In addition, the complex sensor 120 is mounted on the electronic element 140 using the external terminals 50 so that both surfaces thereof may be exposed to air. Therefore, even though sensors 20, 30 and 40 are disposed on both surfaces of the complex sensor 120, the sensors 20, 30 and 40 easily contact with air; thus, operation reliability thereof may be secured.

In addition, as an area of the humidity sensor for absorbing water molecules is widened, sensitivity of the humidity sensor may be improved. In this example, since the humidity sensor 40 may be formed over the entire lower surface of the complex sensor 120, a sensing area of the humidity sensor 40 may be significantly increased while the entire size of the complex sensor 120 is significantly decreased. Thus, sensing sensitivity may be improved.

Next, a method of manufacturing a complex sensor according to one example will be described.

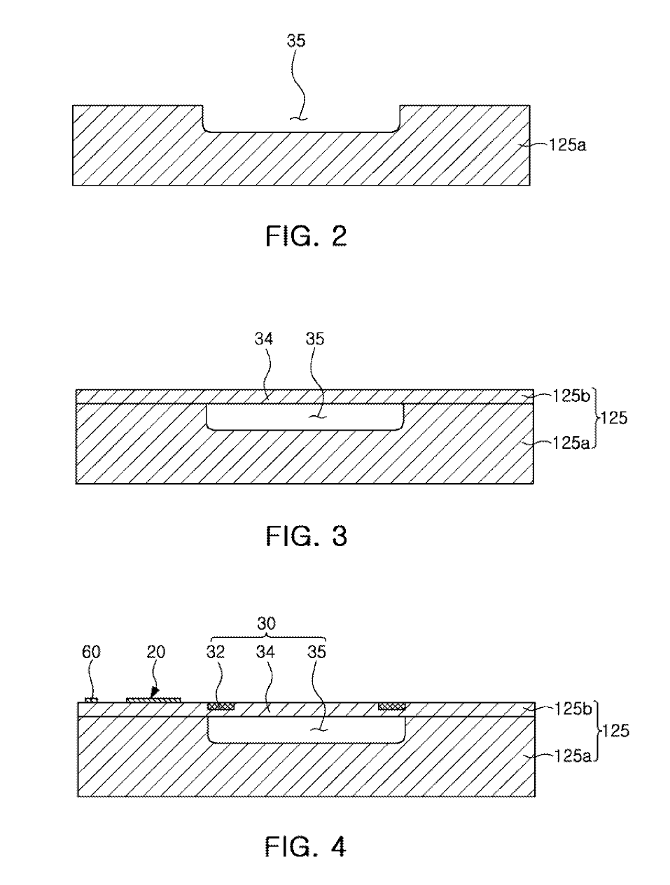

FIGS. 2 through 7 are cross-sectional views illustrating an example of a method of manufacturing a complex sensor package 100.

First, as illustrated in FIG. 2, a cavity 35 is formed in a first substrate 125a.

The first substrate 125a may be a silicon substrate such as, for example, a wafer.

As illustrated, the cavity 35 may have a form of a groove which is open in an upper surface of the first substrate 125a.

Then, as illustrated in FIG. 3, a second substrate 125b is stacked on the first substrate 125a to form the base 125. In this process, the second substrate 125b may cover the open top of the cavity 35 to close the cavity 35.

Similar to the first substrate 125a, the second substrate 125b may be a silicon substrate. In addition, after the second substrate 125b is stacked on the first substrate 125a, it may be partially polished, and thus it formed to have a final thickness that is thinner than that of the first substrate 125a. However, the method of preparing the second substrate 125b is not limited thereto. That is, the thinly polished second substrate 125b may be prepared and then stacked on the first substrate 125a.

In addition, a portion of the second substrate 125b covering the opening of the cavity 35 is formed of the diaphragm 34. Therefore, the second substrate 125b or the diaphragm 34 is formed to have a thickness sufficient to be easily deformed when a predetermined level of pressure is applied thereto.

Meanwhile, in this example, the base 125 may be obtained from a wide silicon substrate in which a plurality of individual element regions are formed, and the wide silicon substrate may be cut according to individual element regions to form the above-mentioned package substrate 110 (see FIG. 1).

Then, as illustrated in FIG. 4, the plurality of piezoresistors 32 and the temperature sensor 20 are formed on one surface of the base 125.

The piezoresistors 32 may be formed by doping the diaphragm 34 with boron, phosphorus, or the like; however, the methods of forming the piezoresistors 32 are not limited thereto.

In addition, the temperature sensor 20 may be formed by forming a pattern resistor on the base 125 using a material (for example, platinum (Pt), nickel (Ni), or polysilicon) having a resistance value that is in proportion to temperature change. However, the method of forming the temperature sensor 20 is not limited thereto.

During the forming of the temperature sensor 20, a conductor pattern (not illustrated) and the upper electrode 60 together with the temperature sensor 20 may also be formed on the base 125.

Therefore, in the illustrated method of manufacturing a complex sensor, after the piezoresistors 32 are formed, the upper electrode 60 and a wiring pattern electrically connecting the piezoresistors 32 to the upper electrode 60 are simultaneously formed during the forming of the temperature sensor 20.

However, the temperature sensor 20 and the piezoresistors 32 are not limited to the above-mentioned sequence. That is, in another example, the piezoresistors 32 may be formed after the temperature sensor 20 is formed, if necessary.

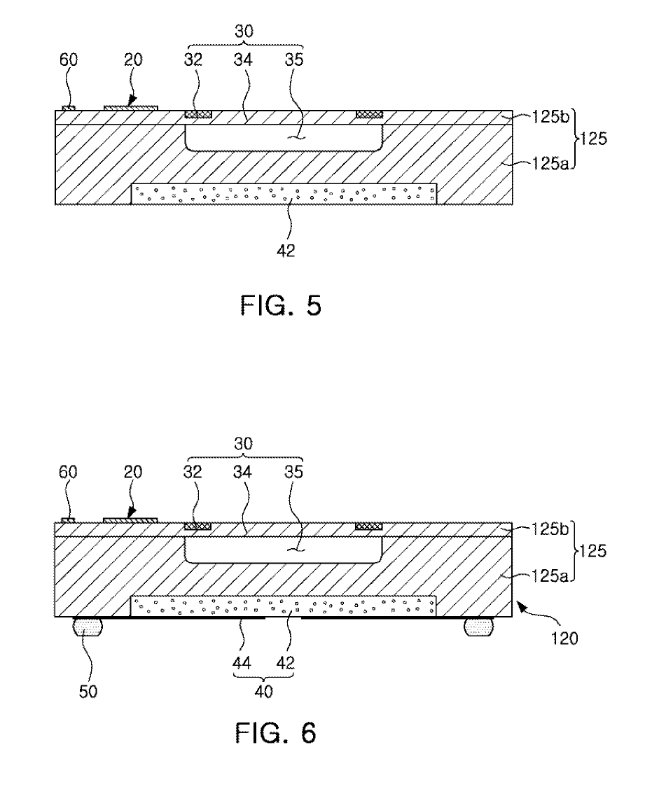

Then, as illustrated in FIG. 5, the porous silicon layer 42 is formed on the other surface of the base 125. The porous silicon layer 42 may be formed by forming a mask (not illustrated) by partially doping the other surface of the base 125 and then immersing the base 125 in hydrofluoric acid (HF) to electrolyze the base.

Therefore, the porous silicon layer 42 may be formed in only a region in which the mask is not formed.

After the porous silicon layer 42 is formed, the electrodes 44 for the humidity sensor, the external terminals 50, and a wiring pattern (not illustrated) electrically connecting the electrodes and the external terminals 50 to each other are formed on the other surface of the base 125, as illustrated in FIG. 6.

The external terminals 50 may have the form of solder balls, solder bumps, or the like.

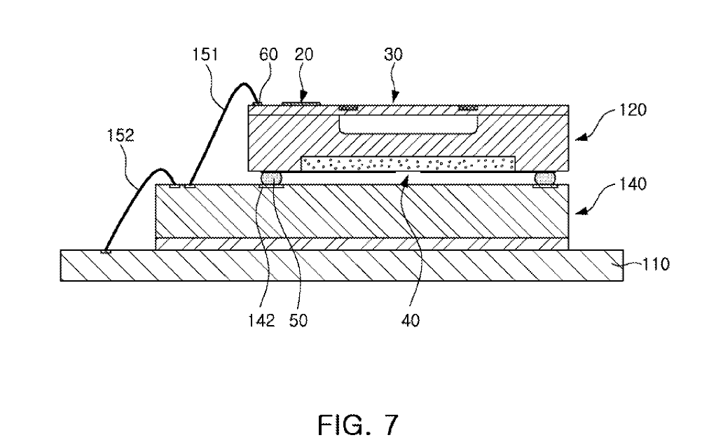

After the complex sensor 120 is completed through the above-mentioned operations, the electronic element 140 is mounted on the package substrate 110, and the complex sensor 120 is mounted on the upper surface of the electronic element 140, as illustrated in FIG. 7.

The external terminals 50 of the complex sensor 120 is bonded to the electrodes 142 formed on the upper surface of the electronic element 140. In addition, the upper electrode 60 formed on the upper surface of the complex sensor 120 is electrically connected to the electronic element 140 through the bonding wire 151.

Further, the electronic element 140 is electrically connected to the package substrate 110 through the bonding wire 152. However, the electronic element 140 is not limited to being electrically connected to the package substrate 110 through the bonding wire 152. In another example, the electronic element 140 may be bonded to the package substrate 110 in a flip chip bonding scheme to accommodate an electronic element 140 that is manufactured in a flip chip form.

Then, the cover 160 is bonded to the package substrate 110 to cover the complex sensor 120 and the electronic element 140, thereby completing the complex sensor package 100 illustrated in FIG. 1.

In the example of the method of manufacturing a complex sensor package described above, the humidity sensor may be formed on the lower surface of the complex sensor using the porous silicon layer. In this case, a temperature limit in subsequent operations may be further raised in comparison to the manufacturing of a metal-insulator-metal (MIM) type humidity sensor.

In addition, since the porous silicon layer sensing humidity is formed as a portion of the base without protruding externally from the base, defects due to scratches of or damages to the porous silicon layer during the manufacturing process may be significantly decreased.

Meanwhile, the present inventive concept is not limited to the above-mentioned examples, and various modifications within the scope of the present disclosure.

FIG. 8 is a cross-sectional view of another example of a complex sensor package.

Referring to FIG. 8, in a complex sensor package 200, the second sensor unit includes the humidity sensor 40 and the gas sensor 70.

Similar to the humidity sensor 40, the gas sensor 70 may be formed using a porous silicon layer.

In more detail, two independent porous silicon layers 42 and 72 are formed during the forming of the porous silicon layer 42 illustrated in FIG. 5. In addition, the electrodes 44 are formed on one of the two independent porous silicon layers 42 and 72 to complete the humidity sensor 40, and a membrane layer 74 is formed on the other of the two independent porous silicon layers 42 and 72 by using a silicon oxide layer, a silicon nitride layer, or the like, and an electrode pattern 76 is formed on the membrane layer 74 to complete the gas sensor 70.

The humidity sensor 40 and the gas sensor 70 are not limited to having the above-mentioned structures, and may be variously modified as long as they use a porous structure (for example, a porous silicon layer).

In addition, the electronic element 140 according to the illustrated example have a groove 145 formed in an upper surface thereof. In this example, the groove 145 is of a size corresponding to a sensing area of the second sensor unit including the humidity sensor 40 and the gas sensor 70 formed on the lower surface of the complex sensor 120; however, the size may vary in another example.

Referring to FIG. 8, the above-mentioned groove 145 spans an upper surface of the electronic element 140. Therefore, a wider gap is formed between the electronic element 140 and the complex sensor 120. Consequently, air or gas may be easily introduced into a space between the electronic element 140 and the complex sensor 120, and thus sensing sensitivity and reliability may be improved.

As set forth above, in a complex sensor according to various examples described above, a plurality of sensors may be disposed on both surfaces of the complex sensor. Therefore, a size of the complex sensor may be significantly decreased, and thus a size of the complex sensor package may also be significantly decreased.

In addition, the complex sensor may be mounted on the electronic element using the external terminals so that both surfaces thereof may be exposed to air. Therefore, even if the sensors are disposed on both surfaces of the complex sensor, the sensors may easily be in contact with air, and thus operation reliability thereof may be secured.

Further, since the humidity sensor may be formed over an entire lower surface of the complex sensor, an entire size of the complex sensor may be significantly decreased, while a sensing area of the humidity sensor may be significantly increased, and thus sensing sensitivity may be improved.

While various examples have been shown and described above, it will be apparent to those skilled in the art that modifications and variations could be made without departing from the scope of the present invention as defined by the appended claims.

For example, although a case in which the sensors are disposed on the upper and lower surfaces of the base has been illustrated by way of example in the above-mentioned exemplary embodiments, the sensors are not limited thereto, and may be disposed on side surfaces of the base, if necessary.

In addition, although a case in which the temperature sensor and the pressure sensor are disposed on the upper surface of the base has been described by way of example in the above-mentioned examples, the temperature sensor and the pressure sensor are not limited to being disposed on the upper surface of the base, and may be disposed on any one surface of several outer surfaces of the base, respectively.

In addition, although a case in which a complex sensor is mounted on the electronic element has been described by way of example in the above-mentioned examples, a complex sensor is not limited to being mounted on the electronic element, and may also be mounted on a package substrate. When a complex sensor is mounted on a package substrate, a mounting area of the overall complex sensor package may be increased, while a thickness of the complex sensor package may be decreased.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A complex sensor comprising:
a base;
a first sensor unit disposed on a first surface of the base; and
a second sensor unit disposed on a second surface of the base.

2. The complex sensor of claim 1, wherein the first sensor unit is disposed on an upper surface of the base, and
the second sensor unit is disposed on a lower surface of the base.

3. The complex sensor of claim 1, wherein the first sensor unit comprises at least one of a pressure sensor and a temperature sensor, and
the second sensor unit comprises at least one of a humidity sensor and a gas sensor.

4. The complex sensor of claim 1, wherein the second sensor unit comprises a porous silicon layer.

5. The complex sensor of claim 2, further comprising a plurality of external terminals disposed on the lower surface of the base and electrically connected to the second sensor unit.

6. The complex sensor of claim 1, wherein the second sensor unit comprises a porous silicon layer and electrodes disposed on the porous silicon layer.

7. The complex sensor of claim 6, wherein the porous silicon layer is obtained by electrolyzing a portion of the base.

8. The complex sensor of claim 3, wherein the pressure sensor comprises a diaphragm closing a cavity provided in the base and at least one piezoresistor disposed on the diaphragm.

9. The complex sensor of claim 3, wherein the temperature sensor comprises a pattern resistor disposed on one surface of the base.

10. The complex sensor of claim 3, wherein the second sensor unit is electrically connected to an external element through external terminals disposed on a lower surface of the base, and
the first sensor unit is electrically connected to the external element through a bonding wire.

11. A method of manufacturing a complex sensor, the method comprising:
forming a first sensor unit on a first surface of a base; and
forming a second sensor unit on a second surface of the base.

12. The method of claim 11, wherein the forming of the first sensor unit comprises forming a pressure sensor, and
the forming of the pressure sensor comprises:
forming a cavity in a first substrate;
stacking a second substrate on the first substrate to close the cavity; and
forming at least one piezoresistor on the second substrate.

13. The method of claim 12, wherein the forming of the second sensor unit comprises:
forming at least one porous silicon layer on the other surface of the base; and
forming electrodes on the porous silicon layer.

14. The method of claim 13, wherein the forming of the porous silicon layer comprises:
forming a mask on the other surface of the base formed of silicon; and
forming the porous silicon layer by etching the other surface of the base using hydrofluoric acid (HF).

15. The method of claim 13, wherein the forming of the second sensor unit comprises forming a humidity sensor and a gas sensor using the porous silicon layer.

16. The method of claim 12, wherein the forming of the first sensor unit comprises forming a temperature sensor, and
the forming of the temperature sensor comprises forming a pattern resistor on the second substrate, after the forming of the piezo-resistor.

17. A complex sensor package comprising:
the complex sensor of claim 1; and
an electronic element on which the complex sensor is mounted so that both the first surface and the second surface of the base are exposed to air.

18. The complex sensor package of claim 17, further comprising a cover forming a cavity therein, wherein the complex sensor is disposed in the cavity such that the first surface and the second surface of the base are exposed to the air inside the cavity.
